(19) United States
(12) Patent Application Publication
(10) Pub. No.: US 2026/0314454 A1
(43) Pub. Date: Oct. 8, 2026

(54) FLIP-CHIP PACKAGE WITH PRE-MOLDED LEADFRAME

(71) Applicant: Navitas Semiconductor Limited, Dublin (IE)

(72) Inventors: Maria Cristina ESTACIO, Cebu City (PH); Oseob JEON, Seoul (KR); Daniel M. KINZER, El Segundo, CA (US)

(73) Assignee: Navitas Semiconductor Limited, Dublin (IE)

(21) Appl. No.: 19/641,258

(22) Filed: Apr. 7, 2026

Related U.S. Application Data
(60) Provisional application No. 63/784,831, filed on Apr. 7, 2025.

(30) Foreign Application Priority Data
Jun. 3, 2025 (CN) 202510737342.X

(51) Int. Cl. H10W 70/652; H10W 70/05; H10W 70/654; H10W 72/00; H10W 72/20; H10W 90/00

(52) U.S. Cl. CPC H10W 70/6528; H10W 70/05; H10W 70/654; H10W 72/072; H10W 72/248; H10W 90/724; H10W 72/227; H10W 72/228

(57) ABSTRACT

An electronic device may include a package base having a first and second external terminals disposed at a bottom surface. The package base may include an electrically insulative layer having a thickness defined between two surfaces. A plurality of electrically conductive bars may extend from the first external terminal to the first surface. A plurality of first electrically conductive terminals may be disposed on each of the plurality of electrically conductive bars at the first surface. A plurality of second electrically conductive terminals may be disposed on the first surface of the electrically insulative layer. Each second electrically conductive terminal may be disposed between adjacent first electrically conductive terminals. A semiconductor device may be attached to the plurality of first electrically conductive terminals and to the plurality of second electrically conductive terminals. An electrically insulative material may encapsulate at least a portion of the semiconductor device.

### CROSS-REFERENCE TO RELATED APPLICATION

The present application claims priority to U.S. Provisional Patent Application No. 63/784,831 filed on Apr. 7, 2025, entitled “FLIP-CHIP PACKAGE WITH PRE-MOLDED LEADFRAME,” and to Chinese Provisional Patent Application No. 202510737342.X filed on Jun. 3, 2025, entitled “FLIP-CHIP PACKAGE WITH PRE-MOLDED LEADFRAME,” the contents of all of which are incorporated herein by reference in their entirety.

### TECHNICAL FIELD

The described embodiments relate generally to electronic devices and electronic device packaging. More particularly, the present embodiments relate to packaging for semiconductor devices that attach to a pre-molded leadframe package base.

### BACKGROUND

Conventional power semiconductor packages may suffer from high electrical resistance and inductance that can limit device performance. Existing approaches for packaging power systems may include solder-bump arrays mounted directly on printed circuit boards, which can present assembly complexity and may be limited by solder bump stand-off resistance and contact density constraints. Additionally, conventional packages may provide limited thermal management options and may not readily accommodate standard footprint requirements for drop-in compatibility with existing circuit designs.

### SUMMARY OF THE DISCLOSURE

According to one aspect, an electronic device may include a package base having a first external terminal and a second external terminal disposed at a bottom surface of the package base. The package base may include an electrically insulative layer having a first thickness defined between a first surface and a second surface. A plurality of electrically conductive bars may extend from the first external terminal to the first surface. A plurality of first electrically conductive terminals may be disposed on each of the plurality of electrically conductive bars at the first surface. A plurality of second electrically conductive terminals may be disposed on the first surface of the electrically insulative layer. Each of the plurality of second electrically conductive terminals may be disposed between adjacent first electrically conductive terminals. A semiconductor device may be attached to the plurality of first electrically conductive terminals and to the plurality of second electrically conductive terminals. An electrically insulative material may encapsulate at least a portion of the semiconductor device and the package base.

In some embodiments, the semiconductor device may comprise a semiconductor die having a plurality of source contacts and a plurality of drain contacts arranged in an interdigitated pattern. The plurality of source contacts may be electrically coupled to the plurality of second electrically conductive terminals and the plurality of drain contacts may be electrically coupled to the plurality of first electrically conductive terminals. An electrically conductive via may extend through the electrically insulative layer and may electrically couple at least one of the plurality of second electrically conductive terminals to the second external terminal. An electrically conductive collector may be disposed on the first surface of the electrically insulative layer and may be electrically coupled to the plurality of second electrically conductive terminals. The electrically conductive collector may be electrically coupled to the second external terminal through the electrically conductive via extending through the electrically insulative layer. The semiconductor device may comprise gallium nitride (GaN). The plurality of electrically conductive bars may comprise copper. The plurality of source contacts and the plurality of drain contacts may have substantially similar widths.

According to another aspect, an electronic device may comprise a semiconductor die including a plurality of source contacts interdigitated with a plurality of drain contacts. A plurality of electrically conductive drain bars may be aligned with and attached to the plurality of drain contacts. An exterior drain terminal may be attached to the plurality of electrically conductive drain bars. A plurality of electrically conductive source bars may be aligned with and attached to the plurality of source contacts. An exterior source terminal may be electrically connected to each of the plurality of electrically conductive source bars.

In some embodiments, one or more electrically insulative materials may at least partially encapsulate the semiconductor die and the plurality of electrically conductive drain bars. A first electrically insulative material may at least partially encapsulate the semiconductor die and a second electrically insulative material may at least partially encapsulate the drain bars. The second electrically insulative material may be formed as a layer having a top surface opposite a bottom surface and wherein each of the exterior drain terminal and the exterior source terminal may be at the bottom surface. The semiconductor device may further comprise an electrically conductive source via extending through the layer and electrically connecting the exterior source terminal to the plurality of electrically conductive source bars. The electronic device may further comprise an electrically conductive source collector electrically coupled to each of the plurality of electrically conductive source bars and wherein the electrically conductive source via may electrically connect the source collector to the exterior source terminal. The semiconductor die may comprise gallium nitride. The plurality of source contacts and the plurality of drain contacts may have substantially similar widths.

According to another aspect, a method for forming the electronic device may comprise providing a package base comprising a first external terminal and a second external terminal disposed at a bottom surface of the package base. The method may comprise forming an electrically insulative layer having a first thickness defined between a first surface and a second surface. The method may comprise forming a plurality of electrically conductive bars extending from the first terminal to the first surface. The method may comprise disposing a plurality of first electrically conductive terminals on each of the electrically conductive bars at the first surface. The method may comprise disposing a plurality of second electrically conductive terminals on the first surface of the electrically insulative layer, each of the second electrically conductive terminals disposed between adjacent first electrically conductive terminals. The method may comprise attaching a semiconductor device to the plurality of first electrically conductive terminals and to the plurality of second electrically conductive terminals. The method may comprise encapsulating at least a portion of the semiconductor device and the package base with an electrically insulative material.

In some embodiments, the semiconductor device may comprise a plurality of source contacts arranged in an interdigitated pattern. Attaching the semiconductor device may comprise electrically coupling the plurality of source contacts to the plurality of second electrically conductive terminals and electrically coupling the plurality of drain contacts to the plurality of first electrically conductive terminals. The method may further comprise forming an electrically conductive via extending through the electrically insulative layer and electrically coupling at least one of the plurality of second electrically conductive terminals to the second external terminal. The method may further comprise forming an electrically conductive collector disposed on the first surface of the electrically insulative layer and electrically coupled to the plurality of second electrically conductive terminals, wherein the electrically conductive collector may be electrically coupled to the second external terminal through the electrically conductive via. The semiconductor device may comprise gallium nitride.

Those skilled in the art will appreciate various additional embodiments upon reading the following detailed description of the embodiments with reference to the below-listed drawing figures. It is within the scope of the present disclosure that the above-discussed aspects be provided both individually and in various combinations.

### BRIEF DESCRIPTION OF THE DRAWINGS

According to common practice, the various features of the drawings discussed below are not necessarily drawn to scale. Dimensions of various features and elements in the drawings may be expanded or reduced to more clearly illustrate the embodiments of the disclosure.

FIG. 1A is a bottom perspective view of an electronic device including a package base according to an embodiment of the disclosure.

FIG. 1B is a simplified partial cross-section view along line A-A of the electronic device shown in FIG. 1A.

FIG. 2 is a simplified flow chart of an example fabrication method that may be used to make the electronic device shown in FIG. 1A.

FIG. 3A is a simplified bottom view of the package base structure for the electronic device shown in FIG. 1A in a first step of a fabrication method, according to some embodiments of the disclosure.

FIG. 3B is a simplified cross-section view along line B-B of the package base structure shown in FIG. 3A.

FIG. 4A is a simplified bottom view of the package base structure in a second step of the fabrication method, according to some embodiments of the disclosure.

FIG. 4B is a simplified cross-section view along line C-C of the package base structure shown in FIG. 4A.

FIG. 5A is a simplified bottom view of the package base structure in a third step of the fabrication method, according to some embodiments of the disclosure.

FIG. 5B is a simplified cross-section view along line D-D of the package base structure shown in FIG. 5A.

FIG. 6A is a simplified bottom view of the package base structure in a fourth step of the fabrication method, according to some embodiments of the disclosure.

FIG. 6B is a simplified cross-section view along line E-E of the package base structure shown in FIG. 6A.

FIG. 7A is a simplified bottom view of the package base structure in a fifth step of the fabrication method, according to some embodiments of the disclosure.

FIG. 7B is a simplified cross-section view along line F-F of the package base structure shown in FIG. 7A.

FIG. 8 is a simplified top view of the semiconductor die for the electronic device, according to some embodiments of the present disclosure.

FIG. 9A is a semi-transparent bottom view of the package base with the die attached to the package base, according to some embodiments of the present disclosure.

FIG. 9B is a simplified cross-section view along line G-G of the package base structure shown in FIG. 9A.

FIG. 10A is a simplified top view of the electronic device, according to some embodiments of the present disclosure.

FIG. 10B is a simplified cross-section view along line H-H of the package base structure shown in FIG. 10A.

FIG. 11 is a simplified top view of a package base, according to a second embodiment of the present disclosure.

FIG. 12 is a simplified top view of a semiconductor die for the electronic device, according to a second embodiment of the present disclosure.

FIG. 13A is a semi-transparent top view of an electronic device, according to a second embodiment of the present disclosure.

FIG. 13B is a simplified cross-section view along line A-A of the electronic device shown in FIG. 13A.

FIG. 14A is a semi-transparent top view of an electronic device, according to a third embodiment of the present disclosure.

FIG. 14B is a semi-transparent top view of an electronic device, according to a fourth embodiment of the present disclosure.

Corresponding parts are designated by corresponding reference numbers throughout the drawings.

### DETAILED DESCRIPTION

In the following description, various embodiments will be described. For purposes of explanation, specific configurations and details are set forth in order to provide a thorough understanding of the embodiments. However, it will also be apparent to one skilled in the art that the embodiments may be practiced without the specific details. Furthermore, well-known features may be omitted or simplified in order not to obscure the embodiment being described.

Techniques disclosed herein relate generally to electronic devices and electronic device packaging. More specifically, techniques disclosed herein relate to electronic devices including a semiconductor die attached to a package base that may include multiple electrically conductive bars and interdigitated electrically conductive terminals, and that may provide both a high contact coverage and a reduced drain-to-source pitch resulting in low impedance and low parasitic inductance. Various embodiments are described herein, including methods, processes, systems, devices, and the like.

In order to better appreciate the features and aspects of flip-chip electronic packages with pre-molded leadframes according to the present disclosure, further context for the disclosure is provided in the following section by discussing one particular implementation of a flip-chip electronic package according to embodiments of the present disclosure. These embodiments are for example only and other geometries, arrangement of structures and configurations can be employed in other electronic packages and/or semiconductor devices, and are within the scope of this disclosure.

In some embodiments, an electronic device may include a semiconductor die attached to a package base in a flip-chip configuration. The package base may be fabricated through a multi-step photolithographic and electroplating process, resulting in a structured substrate that may accept the semiconductor die in the flip-chip configuration. The package base may include a plurality of electrically conductive bars embedded within a first electrically insulative layer, with a plurality of interdigitated electrically conductive terminals disposed on a top surface of the first electrically insulative layer. The interdigitated electrically conductive terminals may provide a high density of electrical connections between the semiconductor die and the package base. The package base may further include a plurality of electrically conductive pillars that may provide vertical electrical pathways from the interdigitated terminals at the top surface of the package base to external terminals at a bottom surface of the package base. The external terminals at the bottom surface may be configured for surface-mount assembly on a printed circuit board.

The semiconductor die may include a plurality of source contacts interdigitated with a plurality of drain contacts on an active face of the die. The semiconductor die may be oriented face-down over the package base such that the source contacts may be aligned with and attached to a plurality of source terminals of the package base, and the drain contacts may be aligned with and attached to a plurality of drain terminals of the package base. A drain-to-source pitch of the interdigitated terminals on the package base may be approximately two hundred micrometers or less. This pitch may enable a high density of electrical connections between the semiconductor die and the package base, which may reduce overall package resistance and parasitic inductance.

The package base may function as a redistribution layer without requiring any redistribution layer processing at the die or wafer level. The semiconductor die may employ a standard metallization scheme, with terminal redistribution performed by the package base structure. A second electrically insulative material may encapsulate at least a portion of the semiconductor die and the package base to form the completed electronic device. In some embodiments, a backside surface of the semiconductor die may be exposed through a top surface of the second electrically insulative material to provide a thermal interface for attachment of a heatsink. The package base may be configured to present external drain, source, and gate terminals at the bottom surface of the electronic device in a land grid array format compatible with standard printed circuit board reflow soldering processes. In some embodiments, the semiconductor die may include gallium nitride; however, in other embodiments the semiconductor die may include silicon, silicon carbide, or other suitable semiconductor material. In some embodiments the semiconductor die may be any suitable lateral or vertical field-effect transistor (FET).

Several illustrative embodiments will now be described with respect to the accompanying drawings, which form a part hereof. The ensuing description provides embodiment(s) only and is not intended to limit the scope, applicability, or configuration of the disclosure. Rather, the ensuing description of the embodiment(s) will provide those skilled in the art with an enabling description for implementing one or more embodiments. It is understood that various changes may be made in the function and arrangement of elements without departing from the spirit and scope of this disclosure. In the following description, for the purposes of explanation, specific details are set forth in order to provide a thorough understanding of certain embodiments. However, it will be apparent that various embodiments may be practiced without these specific details. The figures and description are not intended to be restrictive. The word “example” or “exemplary” is used herein to mean “serving as an example, instance, or illustration.” Any embodiment or design described herein as “exemplary” or “example” is not necessarily to be construed as preferred or advantageous over other embodiments or designs.

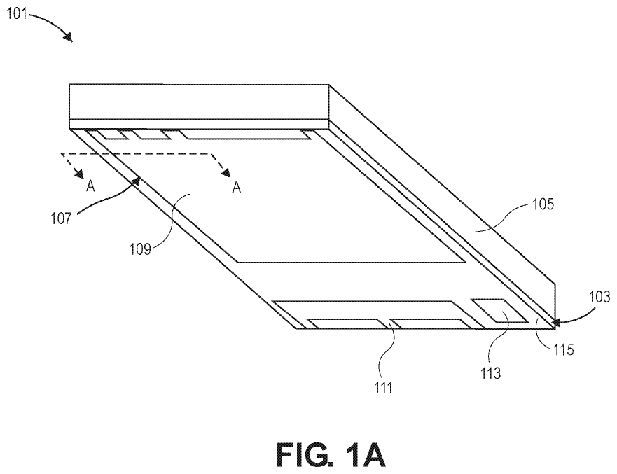

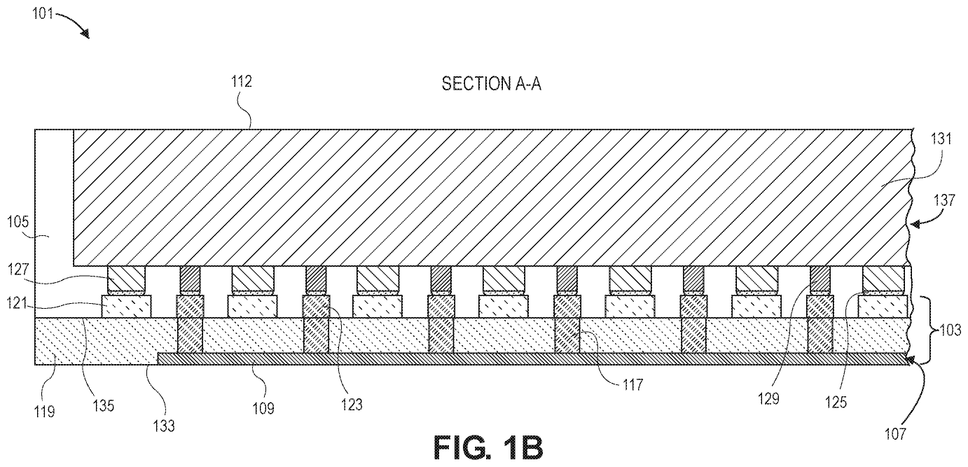

FIG. 1A is a bottom perspective view of an electronic device 101 including a package base 103 according to an embodiment of the disclosure. As shown in FIG. 1A, the electronic device 101 may include a package base 103 that may provide mechanical support and electrical redistribution for a semiconductor die (not visible in FIG. 1A), with the package base 103 presenting a plurality of external terminals at a bottom surface arranged for surface-mount attachment to a printed circuit board. The electronic device 101 may further include a mold cap 105 that may encapsulate at least a portion of the semiconductor die and the package base 103, providing environmental protection and mechanical reinforcement to the completed assembly. The package base 103 may include a conductive base layer 107 that may form a primary electrical plane at the bottom surface of the electronic device 101, with the conductive base layer 107 including a drain region 109, a source region 111, and a gate region 113 that may provide external electrical connections corresponding to drain, source, and gate terminals of the semiconductor die. The drain region 109 may occupy a substantial portion of the bottom surface area to provide a low-resistance electrical connection and efficient thermal dissipation, while the source region 111 and the gate region 113 may be positioned adjacent to the drain region 109 and electrically isolated therefrom by gaps or insulative material within the conductive base layer 107. The external terminals presented at the bottom surface of the electronic device 101 may be configured in a land grid array format compatible with standard printed circuit board reflow soldering processes, enabling the electronic device 101 to be mounted directly onto a printed circuit board without requiring additional lead forming or wire bonding operations.

FIG. 1B is a simplified cross-section view along line A-A of the electronic device 101 shown in FIG. 1A. Looking from the bottom of FIG. 1A to the top, the package base 103 of the electronic device 101 includes the drain region 109 of the conductive base layer 107. A set of conducting rails 117 disposed on the drain region 109 are separated horizontally from one another by a first insulating layer 119 that may be made from a polymer or other suitable electrically insulative material. The conducting rails 117 can be referred to as electrically conducting bars and may be made from copper or other suitable electrically conductive material. The first insulating layer 119 extends from a bottom surface 133 of the electronic device 101 to a top surface 135 of the first insulating layer. A plurality of elongated drain fingers 123 extend above the conducting rails 117 and a plurality of elongated source fingers 121 are disposed on the top surface 135 of the first insulating layer 119. The elongated drain and source fingers, 123, 121, respectively, can be electrically conductive and may be formed from copper or other suitable electrically conductive material.

A semiconductor die 137 is attached to the package base 103 via a flip-chip configuration. Drain terminals 129 of the semiconductor die 137 are attached to each elongated drain finger 123 and source terminals 127 of the semiconductor die 137 are attached to each elongated source finger 121. A substrate 131 of the semiconductor die 137 is exposed to form a portion of a top surface 112 of the electronic device 101 and a second insulating layer or a mold cap 105 is formed around an outer perimeter of the semiconductor die 137 and may be coplanar with or recessed with respect to a top surface of the substrate 131. In some embodiments a top surface of the semiconductor die 137 can be exposed while in other embodiments it may be covered by the mold cap 105. Although not shown in FIG. 1B one or more polymer materials (e.g., molding material, underfill material, etc.) may be disposed between the semiconductor die 137 and the package base 103.

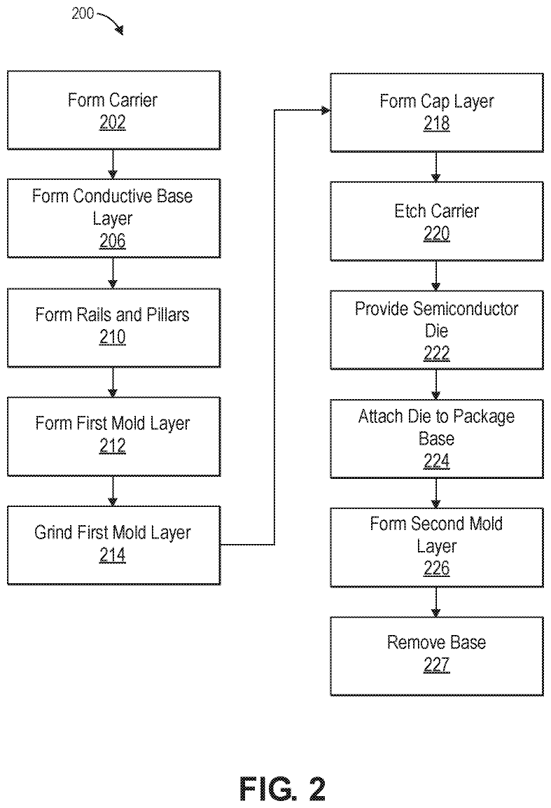

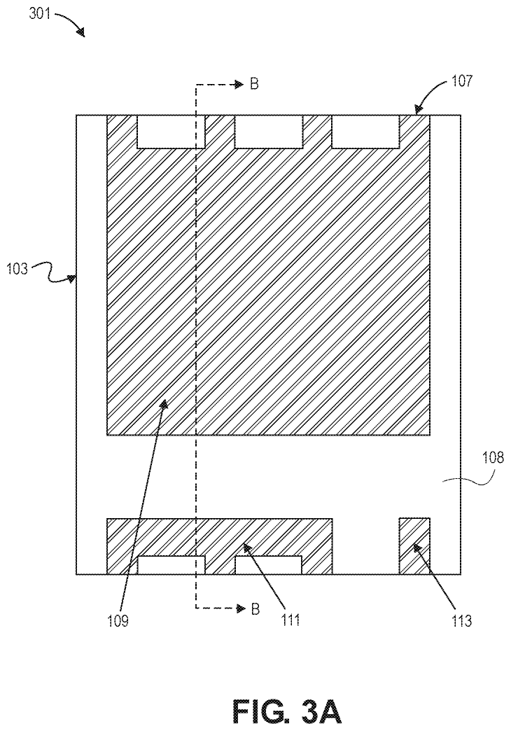

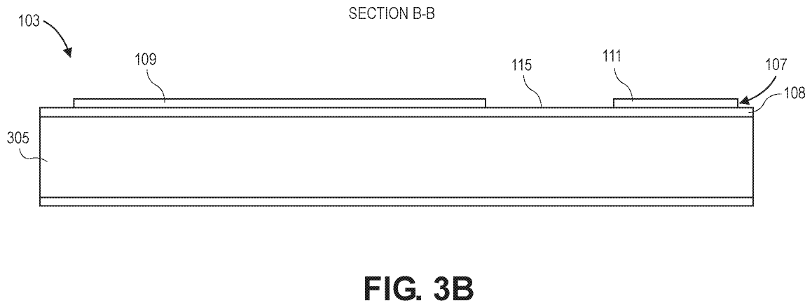

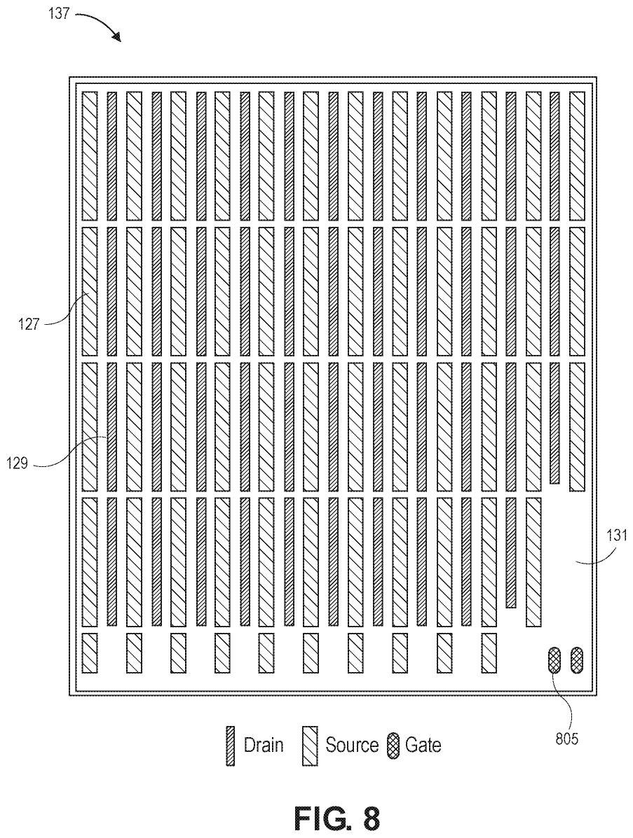

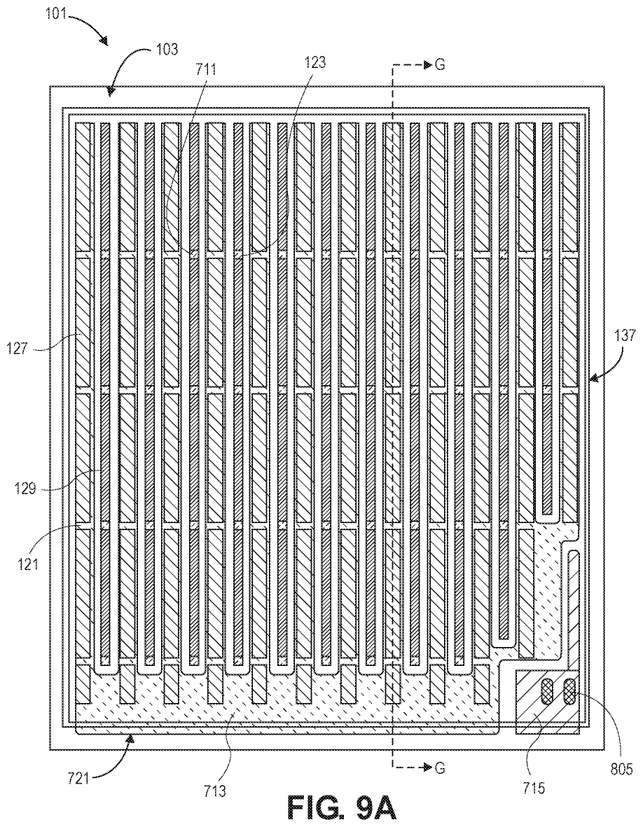

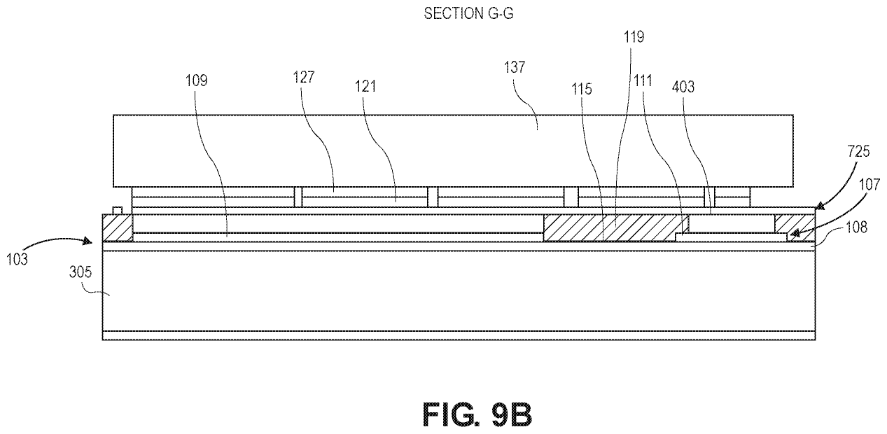

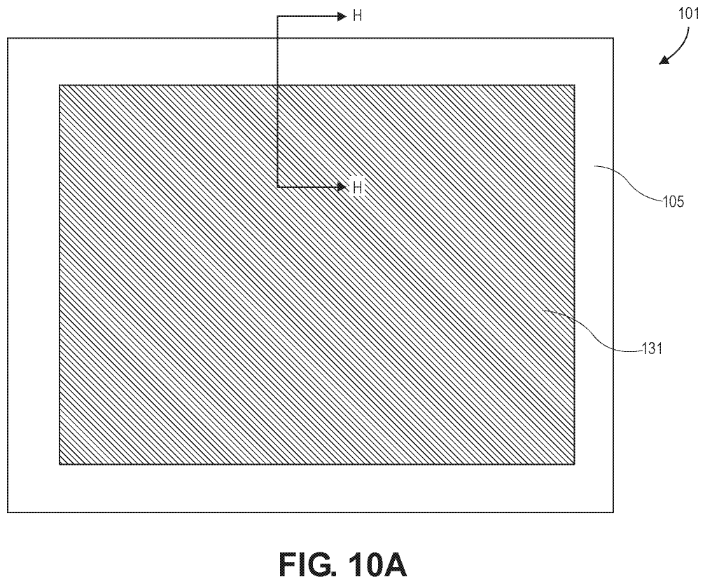

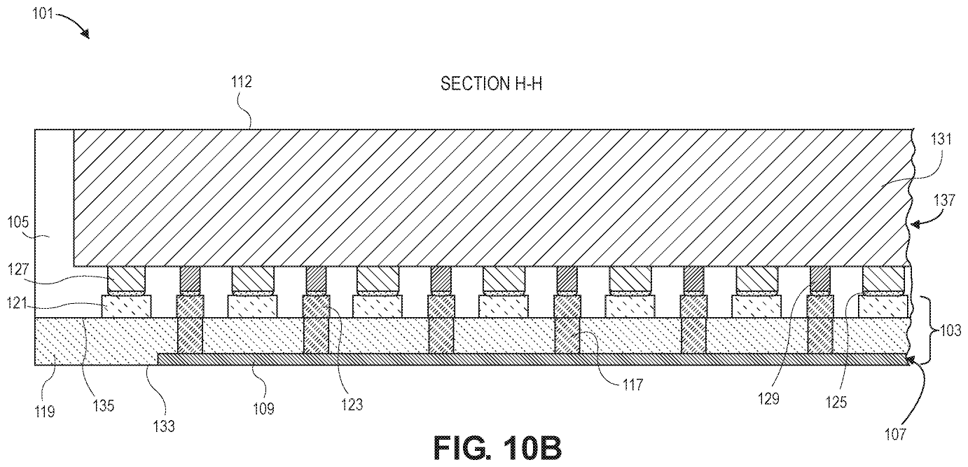

FIG. 2 illustrates steps associated with a method 200 of forming the electronic device 101, according to embodiments of the disclosure. The disclosed approach may provide enhanced electrical performance through interdigitated contact arrangements and reduced parasitic resistance via direct die-to-terminal connections. FIGS. 3A-7B illustrate simplified top views and simplified cross-sectional views of the package base 103 as it is formed on a device structure 301 that includes a carrier 305. FIG. 8 illustrates a simplified top view of the semiconductor die 137 and FIGS. 9A-10B illustrate simplified top views and simplified cross-sectional views of the final steps of forming the electronic device.

At step 202 the method 200 includes forming a carrier. As shown in FIGS. 3A and 3B the carrier can include a base 305 that may be a metal, a ceramic a polymer or other suitable material. In some embodiments the base 305 may be steel. The package base 305 may include a sacrificial layer 108 extending across the bottom surface.

At step 206 the method 200 includes forming a conductive base layer. As shown in FIGS. 3A and 3B the conductive base layer 107 is disposed on the sacrificial layer 108. In some embodiments the conductive base layer 107 is deposited across the sacrificial layer 108 and is patterned via photolithographic processing and etching to form the drain region 109, source region 111 and gate region 113, however in other embodiments a photolithographic mask may be deposited on the sacrificial layer 108 and the drain region, source region and gate regions may be selectively formed. Other suitable processes may be used for form conductive base layer 107. In some embodiments conductive base layer 107 may include one or more layers e.g., a copper layer terminated with layers of silver, nickel, gold, etc.

A thickness of the conductive base layer 107 can be about 50 microns. For example, the conducting region thickness can be between 20 and 30 microns, between 30 and 40 microns, between 40 and 50 microns, between 50 and 60 microns, between 60 and 70 microns, between 70 and 80 microns, etc. Examples of materials that can be used to form the conductive base layer 107 include copper, silver, gold, platinum, palladium, aluminum, some combination of metals, conducting polymer, conductive ink, etc.

While the base conducting layer 107 of the package base 103 is shown with three conducting regions in FIG. 3A, the base conducting layer 107 can include any number of conducting regions. For example, each of the drain, source, or gate regions 109, 111, 113 can be formed from multiple regions instead of a single region. A simplified cross-section of a portion of the device structure 301 during step 206 of the process 200 is shown in FIG. 3B. In some embodiments, the first PL mask may be removed while in other embodiments it may remain for the subsequent step.

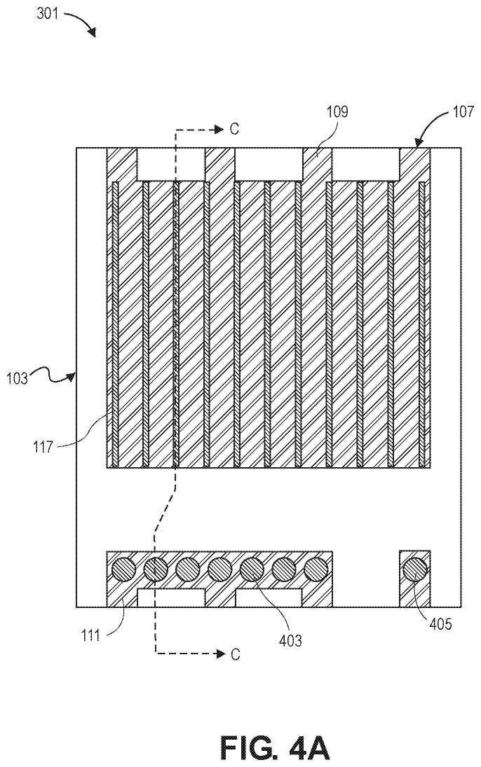

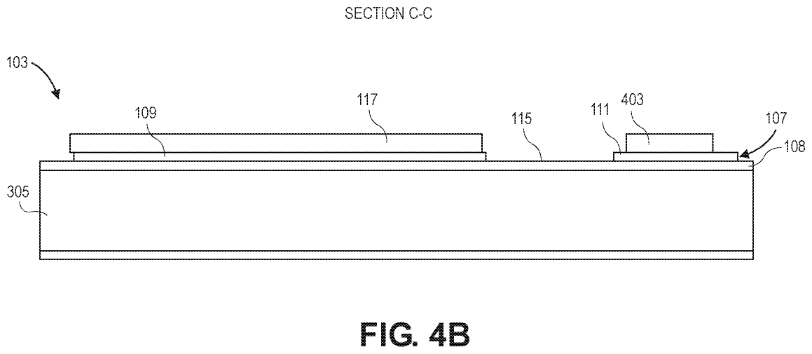

At step 210 the method 200 includes forming rails and pillars on the conducting layer 107. As shown in FIGS. 4A and 4B, conducting rails 117 can be formed within the drain region 109 and conducting pillars 403, 405 can be formed within the source region 111 and the gate region 113. In some embodiments the rails and pillars are formed by first depositing a layer (e.g., copper) across the conducting layer and/or remaining photolithographic mask and patterning it via photolithographic processing and etching to form the conducting rails 117 and conducting pillars 403, 405, however in other embodiments a photolithographic mask may be deposited on the conducting layer and the conducting rails and conducting pillars may be selectively formed. Other suitable processes may be used for forming the conducting rails 117 and conducting pillars 403, 405.

A rail thickness of the conducting rails 117 can match a pillar thickness of the conducting pillars 403, 405 formed in the source and gate regions 111, 113. The rail thickness or pillar thickness can be thicker than the thickness of the three conducting regions formed in the first step of the fabrication process. In some embodiments the rail thickness can be about 150 microns. For example, the rail thickness can be between 50 and 80 microns, between 80 and 110 microns, between 110 and 140 microns, between 140 and 170 microns, between 170 and 200 microns, between 200 and 230 microns, etc.

The conducting rails 117 and conducting pillars 403, 405 can be formed from a same metal or a different metal than the metal that formed the three conducting regions. In one embodiment the conducting base layer 107, the conducting rails 117, and the conducting pillars 403, 405 can all be formed from electroplated copper. Alternatively, the conducting base layer 107 can be formed from copper, while the conducting rails 117 are formed from silver, and the conducting pillars 403, 405 are formed from platinum. The conducting rails 117 can be formed with a length that is considerably longer than a width. For example, the length can be twice as large as the width, five times as large as the width, ten times as large as the width, a hundred times as large as the width, etc. Both the length and the width can be larger than the rail thickness of the conducting rail 117.

In FIG. 4A, the conducting pillars 403, 405 are shown as cylinders with circular cross sections. Alternatively, the conducting pillars 403, 405 can involve cross sections of any suitable shape. For example, the conducting pillars 403, 405 can be formed as cuboids, triangular prisms, hexagonal prisms, pyramids, inverted pyramids, cones, inverted cones, spheres, etc. Source pillars 403 can take on different shapes than the gate pillar 405 and some source pillars 403 can be shaped differently than other source pillars 403. While eleven conducting rails 117 are shown in FIG. 4A, a number of the conducting rails 117 disposed on the drain region 109 can take on any value, including a single conducting rail 117. Likewise, while seven source pillars 403 and a single gate pillar 405 are shown in FIG. 4A, the package base 103 can include any number of source pillars 403 and any number of gate pillars 405.

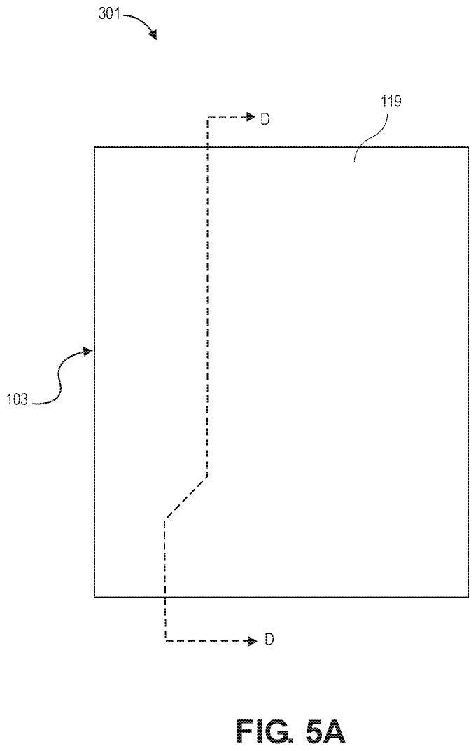

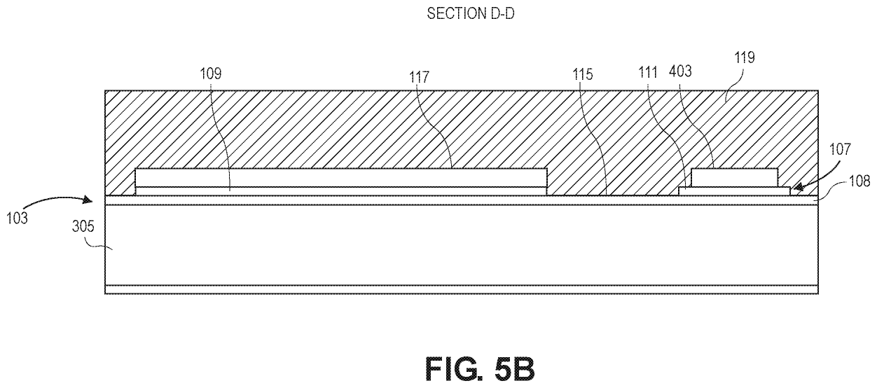

At step 212 the method 200 of FIG. 2 includes forming a first mold layer across the surface of the package base. As shown in FIGS. 5A and 5B, a dielectric molding material (e.g., the first insulating layer 119) is formed and extends across a top surface of the package base 103. The insulating layer 119 is electrically insulative and can be formed from any suitable material, such as a polymer, epoxy resin, silicone, polyurethane, etc. and may include one or more filler materials e.g., ceramic particulates. Step 212 can be referred to as a first molding step of the fabrication process. The insulating layer 119 can cover the base conducting layer 107, the conducting rails 117, the source pillars 403, and the gate pillar 405. A thickness of the insulating layer 119 during step 212, measured from the base surface 115 of the package base 103 to a top surface of the insulating layer 119 can be greater than combined thicknesses of the base conducting layer 107 and the conducting rails 117 or the base conducting layer 107 and the conducting pillars 403, 405. The insulating layer 119 can encapsulate at least a portion of the package base 103.

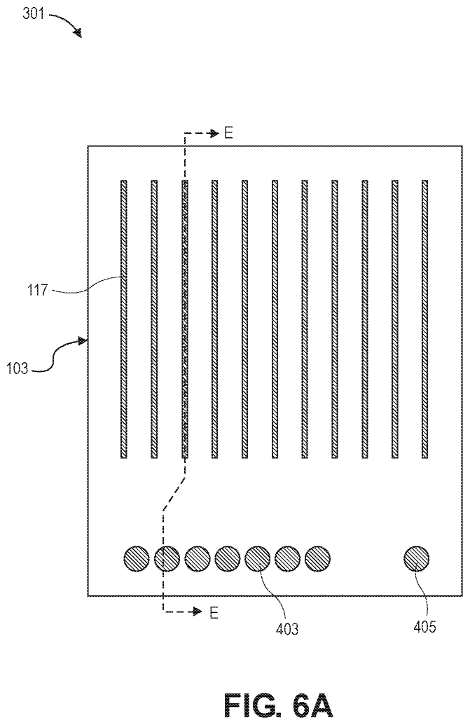

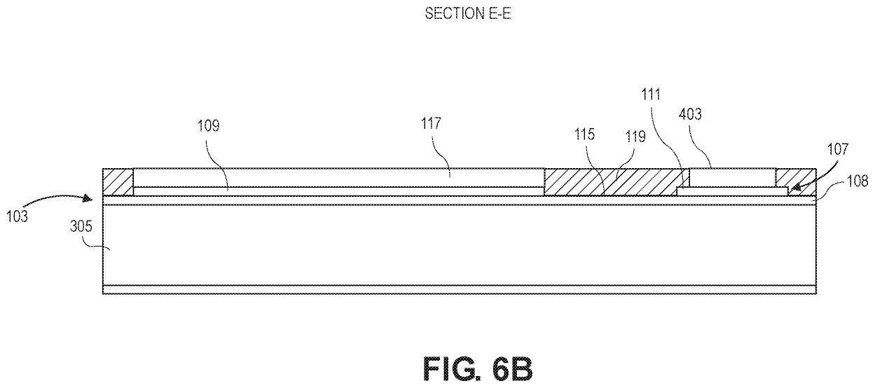

At step 214 the method 200 of FIG. 2 includes grinding the first mold layer. As shown in FIGS. 6A and 6B the insulating layer 119 can be ground down until the top surface of the insulating layer 119 is level with exposed top surfaces of the conducting drain rails 117, the source pillars 403, and the gate pillar 405. The grinding can be performed by any suitable process including chemomechanical polishing.

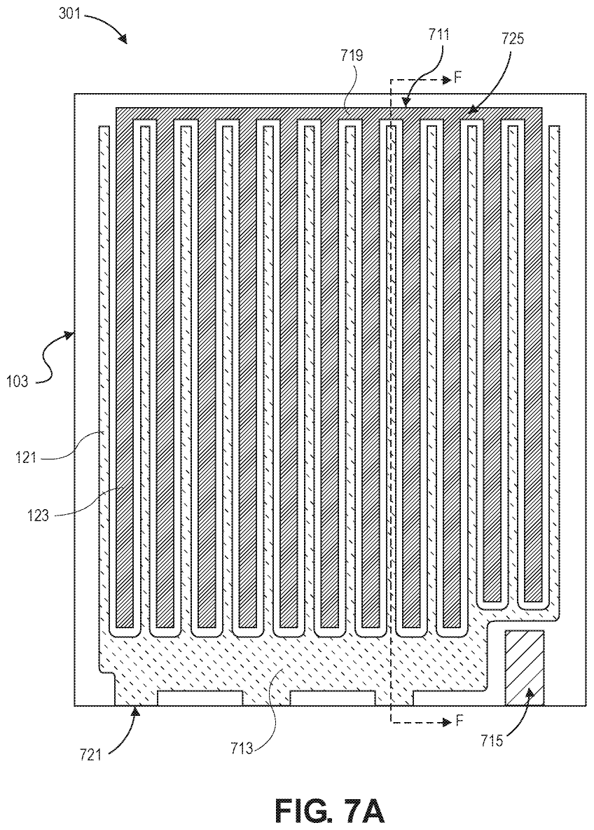

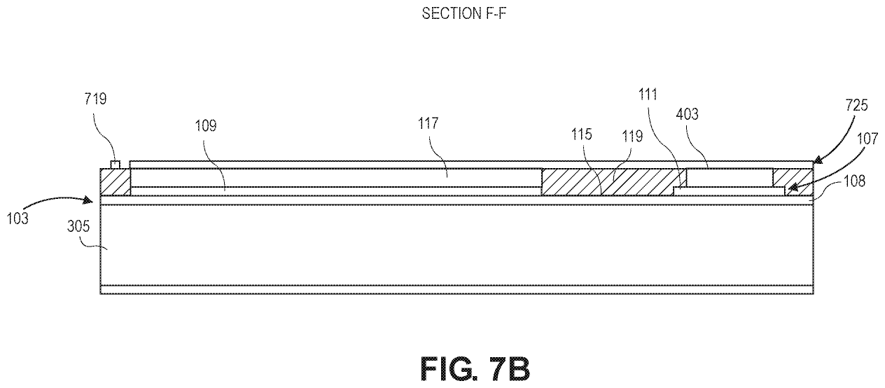

At step 218 the method 200 of FIG. 2 includes forming a cap layer. As shown in FIGS. 7A and 7B a cap layer 735 is formed on a top surface of the package base that was formed via grinding in the previous step. In some embodiments the cap layer 735 is deposited across the ground surface and is patterned via photolithographic processing and etching to form drain, source, and gate caps 711, 721, 715, respectively, however in other embodiments a photolithographic mask may be deposited on the ground surface and the drain, source, and gate caps may be selectively formed. Other suitable processes may be used for form cap layer 735.

A first area of deposited conductive material, or drain cap 711, at least partially covers the exposed surfaces of the conducting rails 117. The drain cap 711 includes terminals or the first set of elongated fingers 123. Each elongated finger 123 of the drain cap 711 covers an exposed top cross section of a single conducting rail 117. The drain cap 711 also includes an optional drain bar 719 that connects the elongated fingers 123 together. In some embodiments, the drain bar 719 is not included as part of the drain cap 711 and the elongated fingers 123 are isolated from each other. Widths of the elongated fingers 123 of the drain cap 711 can be greater than the conducting rails 117 so that at least a portion of a surface area of each elongated finger 123 extends beyond a top surface of a conductive rail 117. The number of elongated fingers 123 of the drain cap 711 can match the number of conductive rails 117 formed during, or prior to, the rail plating step as described above.

A second area of deposited conductive material, or source cap 721, includes a source bar 713 that at least partially covers the set of exposed top surfaces of the source pillars 403. The second set of elongated fingers 121 or terminals extend from the source bar 713. Each elongated finger 121 of the source cap 721 is disposed between two adjacent elongated fingers 123 of the drain cap 711 such that they are interdigitated. As shown in FIG. 7, widths of the elongated fingers 123 of the drain cap 711 can be greater than widths of the elongated fingers 121 of the source cap 721. Alternatively, or additionally, at least some of the elongated fingers 121 of the source cap 721 can have widths that are greater than, or equal to the widths of at least some of the elongated fingers 123 of the drain cap 711. The number of elongated fingers 121 of the source cap 721 is twelve, or one greater than the number of elongated fingers 123 of the drain cap 711. In other embodiments, the number of elongated fingers 121 in the second set of elongated fingers 121can be equal to, greater than, or less than the number in the first set of elongated fingers 123.

A third area of deposited conductive material, or gate cap 715, at least partially covers the exposed top surface of the gate pillar 405. All three areas of the conductive capping layer 725 can have an equal thickness. The thickness of the conductive capping layer 725 can be similar to the thickness of the base conducting layer 107. The conductive capping layer thickness can be about 50 microns. For example, the capping layer thickness can be between 20 and 30 microns, between 30 and 40 microns, between 40 and 50 microns, between 50 and 60 microns, between 60 and 70 microns, between 70 and 80 microns, between 80 and 200 microns, etc. Any of the materials (e.g., copper, silver, conducting polymer, etc.) described above for forming other conducting regions of the package base 103 can also be used to form the conductive capping layer 725.

At step 222 the method 200 of FIG. 2 includes providing a semiconductor die. As shown in FIG. 8 an example semiconductor die 137 is provided. The semiconductor die 137 can be compatible with the package base 103 described above. For example, the semiconductor die 137 can be placed above the package base 103 and attached via flip chip technology to portions of a top surface of the package base 103. The semiconductor die 137 can be a field-effect transistor that includes a series of terminals, including the source terminals 127, drain terminals 129, and gate terminals 805. The series of terminals can be formed on the semiconductor substrate 131 that can be, for example, gallium nitride, silicon, silicon carbide, etc.

As shown in FIG. 8, the semiconductor die 137 includes twelve truncated or interrupted source terminals 127. The number of source terminals 127 on the semiconductor die 137 is equivalent to the number of elongated fingers 121 of the source cap 721 on the package base 103. The source terminals 127 can be interrupted by discontinuities so that the source terminals 127 form multiple line segments. Looking at FIG. 8 from left to right, each of the first ten source terminals 127 are formed from five separate line segments. One of the five line segments is shorter in length than the other four. The eleventh source line is formed from four separate line segments of equal length, and the twelfth source line is formed from three separate line segments of equal length.

Similarly, as shown in FIG. 8, the semiconductor die 137 includes eleven truncated or interrupted drain terminals 129. The number of drain terminals 129 on the semiconductor die 137 is equivalent to the number of elongated fingers 123 of the drain cap 711 on the package base 103. The drain terminals 129 can be interrupted by discontinuities so that the drain terminals 129 form multiple line segments. Looking at FIG. 8 from left to right, each of the first nine drain terminals 129 are formed from four separate line segments of equal length. The tenth drain line is formed from four separate line segments, with one of the four line segments shorter in length than the other three. The eleventh drain line is formed from three separate line segments of equal length.

The semiconductor die 137 can further include two gate terminals 805. The gate terminals 805 can be considerable shorter in length than both the source terminals 127 and drain terminals 129. While the semiconductor die 137 shown in FIG. 2 has twelve source terminals 127, eleven drain terminals 129, and two gate terminals 805, the semiconductor die 137 can include any number of source terminals 127, drain terminals 129, or gate terminals 805. The source terminals 127, drain terminals 129, and gate terminals 805 can all be formed from metallic structures having a top portion made of material suitable for soldering processing. For example, the source terminals 127, drain terminals 129, and gate terminals 805 can be formed from copper with top portions made from silver and tin (AgSn) that may be suitable for soldering.

At step 224 the method 200 of FIG. 2 includes attaching the semiconductor die to the base. As shown in FIGS. 9A and 9B, the semiconductor die 137 is configured such that when the semiconductor die is placed on top of the package base 103 as a flip-chip, at least a portion of the truncated source terminals 127 can contact the second set of elongated fingers 121 of the source cap 721, at least a portion of the truncated drain terminals 129 can contact the first set of elongated fingers 123 of the drain cap 711, and at least a portion of the gate terminals 805 can contact the gate cap 715 of the package base 103.

The flip-chip attachment of the semiconductor die 137 to the package base 103 may be performed using a solder reflow process that may include applying a layer of flux to the package base 103 and/or the semiconductor die 137 and subjecting the semiconductor die 137 and the package base 103 to solder reflow temperatures. Other suitable methods of attachment can be used, such as but not limited to sintered silver, conductive epoxy, etc. After attachment, an optional cleaning process may be performed to remove residual flux and/or an optional underfill process may be performed to secure the die to the package base.

At step 226 the method 200 of FIG. 2 includes forming a second mold layer that may also be referred to herein as forming a mold cap. As shown in FIGS. 10A and 10B, a second mold layer 105 or mold cap may be formed on the package base and may at least partially encapsulate a portion of the package base and a portion of the semiconductor die 137. In some embodiments the semiconductor die 137 may be exposed, as shown in FIGS. 10A and 10B, however in other embodiments the mold material may cover the semiconductor die. The mold material is electrically insulative and can be formed from any suitable material, such as a polymer, epoxy resin, silicone, polyurethane, etc. and may include one or more filler materials e.g., ceramic particulates. In some embodiments the mold material may be the same as the mold material used in step 214 while in other embodiments it may be different.

At step 227 the method 200 of FIG. 2 includes removing the base of the carrier. As shown in FIGS. 10A and 10B the base 305 of the carrier 103 has been removed via etching, grinding or other suitable process. The sacrificial layer 108 is also removed during the carrier removal process such that the base conducting layer 107 forms a portion of the bottom exterior surface of the electronic device 101. In some embodiments the method 200 may also include a singulation step in which individual electronic devices are separated from one another if they are manufactured using a matrix or strip format. Singulation can be performed using a saw, a laser or other suitable process.

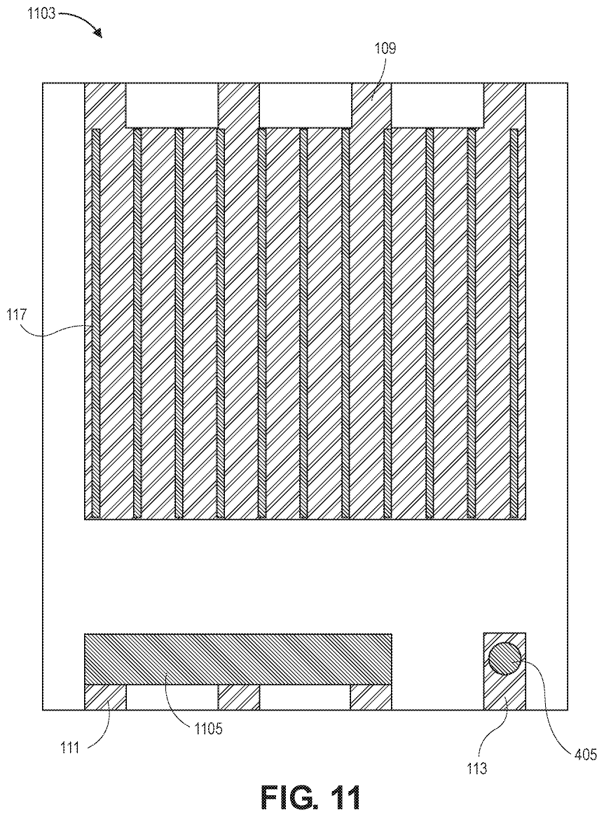

FIG. 11 is a simplified top view of an alternative design of a package base 1103 for the electronic device in a second step of the fabrication process, according to some embodiments of the present application. This alternative design is similar to the design shown above in FIG. 4A, except in this design, the source pillars 403 are replaced by a single source plane 1105.

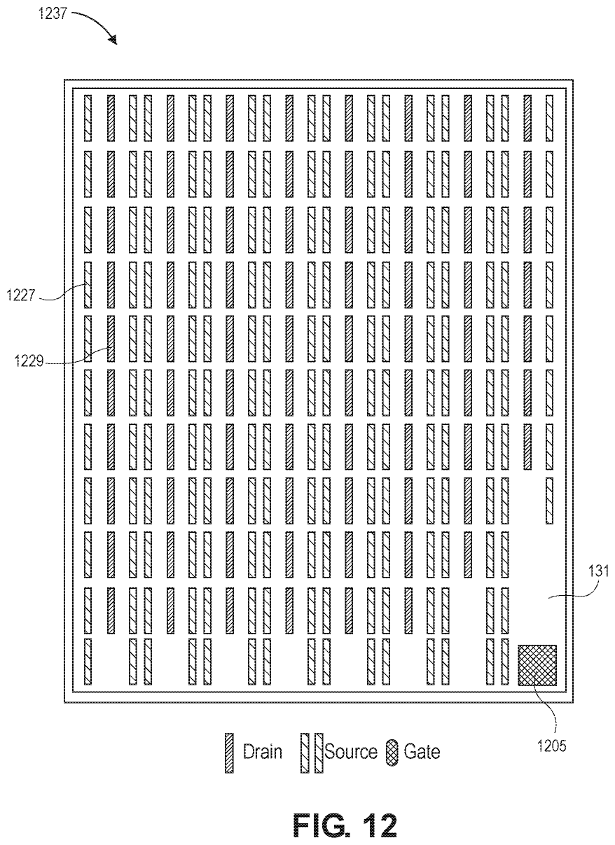

FIG. 12 is a simplified semi-transparent top view of an alternative design of a semiconductor die 1237, according to some embodiments of the present application. This alternative design is similar to the design shown above in FIG. 8, except in this design, source terminals 1227 can have dimensions that are the same as, or similar to, drain terminals 1229 on the semiconductor die 1237. For example, each of the source terminals 1227 and each of the drain terminals 1229 can have substantially identical widths or substantially identical lengths. As defined herein, substantially identical widths or lengths are within 15%, within 10%, within 7%, within 5%, within 2%, or within 1% of each other. Such uniform die pad sizes may result in increased coplanarity of solder tips 125 on the conducting rails 117, source pillars 403, or gate pillar 405, potentially resulting in more reliable manufacturing. The semiconductor die 1237 can be compatible with the package base 103 described in FIG. 7 above. For example, the semiconductor die 1237 can be placed above the package base 103 and attached via flip chip technology (e.g., solder reflow) to portions of a top surface of the package base 103.

As shown in FIG. 12, the semiconductor die 1237 includes 16 columns of truncated or interrupted source terminals 1227. In some embodiments the number of columns of source terminals 1227 on the semiconductor die 1237 can be equivalent to double the number of elongated fingers 121 of the source cap 721 on the package base 103, however, other embodiments may have more or less than double the number of elongated source fingers 121. Each elongated finger 121 of the source cap 721 can be associated with two columns of truncated source terminals 1227. In some examples, elongated fingers 121 of the source cap 721 close to edges of the package base 103 can be associated with one or two columns of truncated source terminals 1227. The semiconductor die 1237 can have twice as many source terminal columns as drain terminal columns due to wider elongated fingers 121 on the source cap 721 on the package base 103.

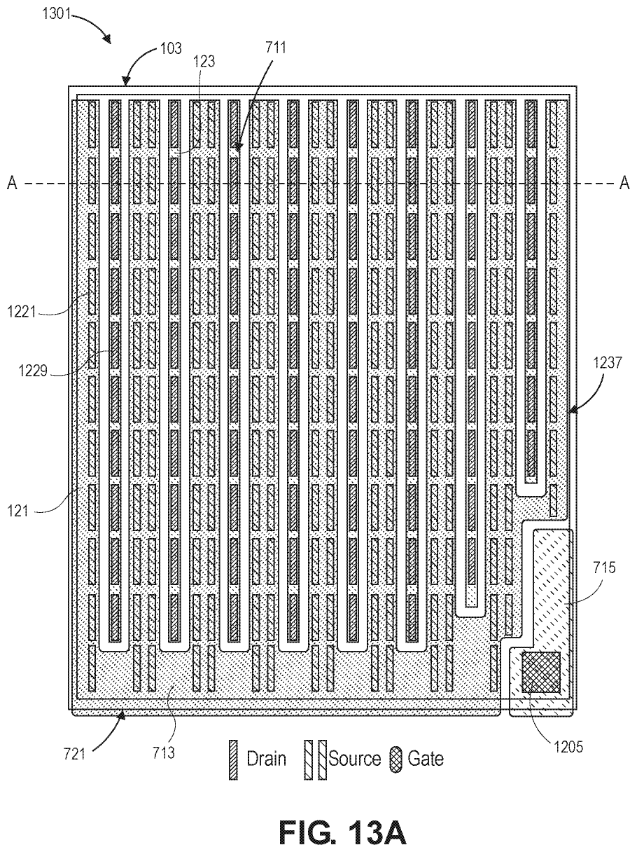

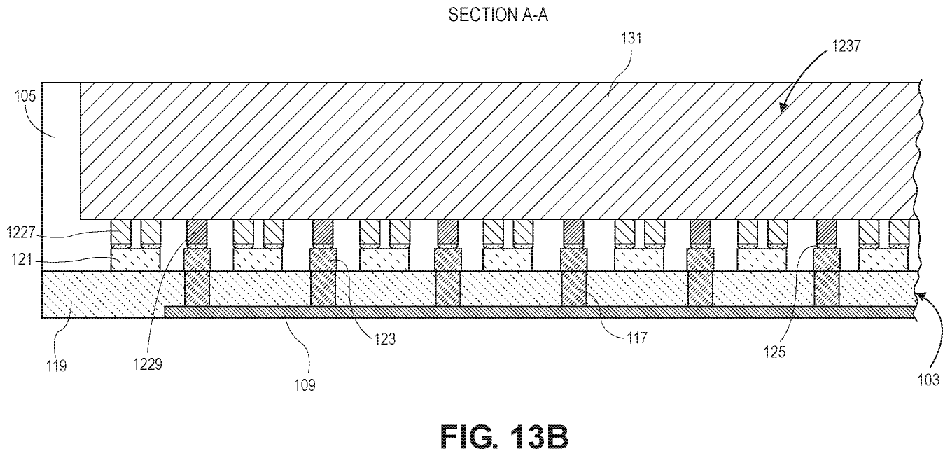

FIG. 13A is a simplified top view of an electronic device 1301 that includes the alternative design of a semiconductor die (e.g., semiconductor die 1237 of FIG. 8) attached to the package base (e.g., package base 103 of FIG. 1A). The electronic device 1301 can be fabricated by attaching the source terminals 1227 of the semiconductor die 1237 to the elongated fingers 121 of a source cap 721 of the package base 103, by additionally attaching drain terminals 1229 of the semiconductor die 1237 to elongated fingers 123 of the drain cap 711 of the package base 103, and by attaching the gate terminal 1205 to the gate cap 715 of the package base 103. The attachment may be performed in a similar manner to the attachment described in the description of FIG. 9 above. However, uniform die pad sizes may result in increased coplanarity of solder tips 125 on conducting pillars 403, 405, potentially resulting in more reliable manufacturing.

FIG. 13B is a simplified cross-sectional view along line A-A of the electronic device 1301 shown in FIG. 13A. Looking from the bottom of FIG. 7B to the top, the package base 103 of the electronic device 1301 includes a base conducting layer 107 of the package base 103. The set of conducting rails 117 are separated horizontally from one another by the first insulating layer 119. The plurality of elongated fingers 123 extending from the drain cap 711 are attached to the conducting rails 117 and the second plurality of elongated fingers 121 extending from the source cap 721 are disposed on a top surface of the first insulating layer 119. A width of each elongated finger of the second plurality of elongated fingers 121 can be greater than a width of each elongated finger of the first plurality of elongated fingers 123. Drain terminals 1229 of the semiconductor die 1237 are attached to each elongated finger 123 of the drain cap 711 and two source terminals 1227 of the semiconductor die 1237 are attached to each elongated finger 121 of the source cap 721. The bulk of the semiconductor die 1237 forms a top layer of the electronic device 1301 and the mold cap 105 is formed around the outer perimeter of the semiconductor die 1237 and on top of a portion of the package base 103.

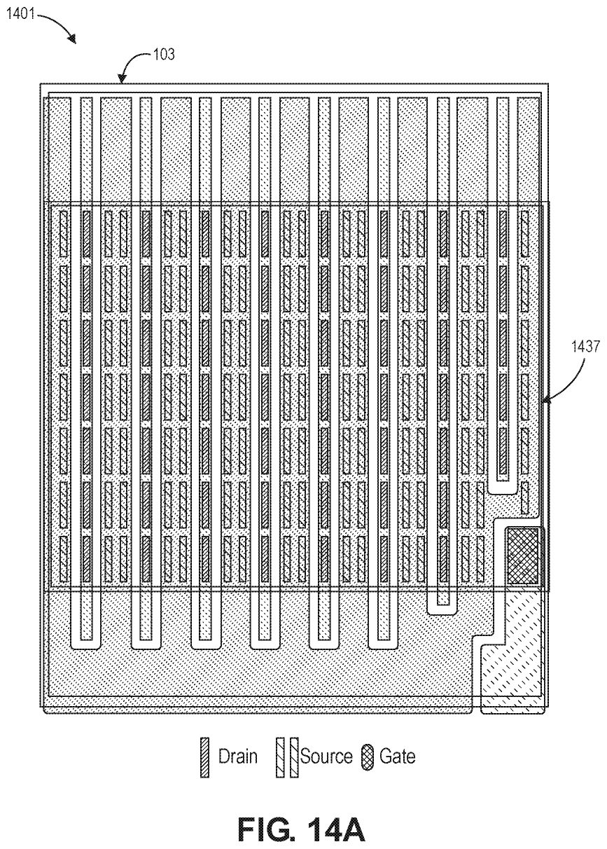

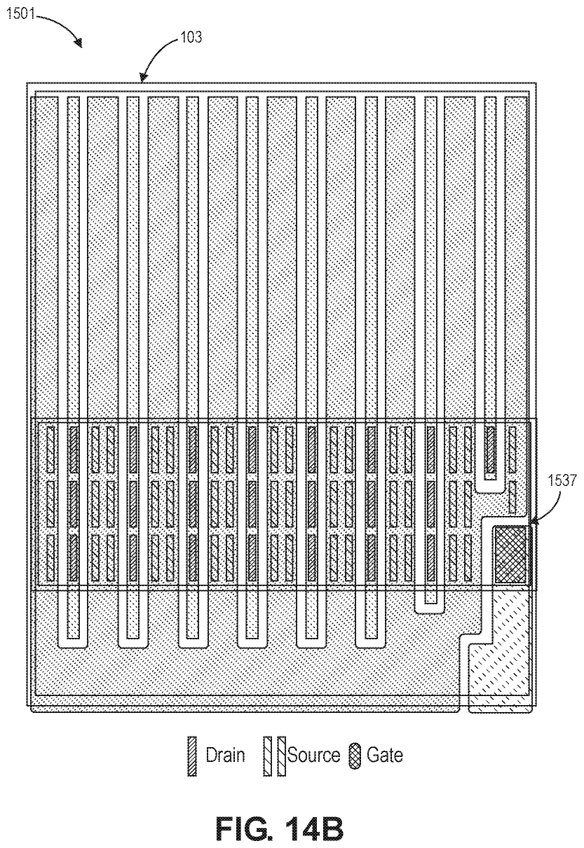

FIG. 14A is a simplified top view of an electronic device 1401 that includes a medium-sized semiconductor die 1437 attached to a package base (e.g., package base 103 of FIG. 7A). FIG. 14B is a simplified top view of an electronic device 1501 that includes a small-sized semiconductor die 1537 attached to a package base (e.g., package base 103 of FIG. 7A). Thus, the same package base 103 can accommodate a wide range of die sizes, minimizing tooling cost and reducing fabrication cycle time. The attachment of the dies to the package base 103 may be performed in a similar manner to the attachment described in the description of FIG. 9A above. The medium semiconductor die 1437 and the small semiconductor die 1537 can be similar to the semiconductor die shown in FIG. 8, but the medium and small semiconductor dies 1437, 1537 can have a smaller length and less rows of source and drain die pads. A single package base can accommodate semiconductor dies of various dimensions.

It will be appreciated that process described above is illustrative and that variations and modifications are possible. Steps described as sequential may be executed in parallel, order of steps may be varied, and steps may be modified, combined, added or omitted.

Terms such as “top”, “bottom”, “up”, or “down” are used herein for illustrative purposes only and do not indicate an absolute orientation of any component or part thereof. For example, a substrate of a power device is herein sometimes referred to as a bottom surface, regardless of an overall orientation of a transistor device. Similarly, a side of the power device that is on an opposite side of such a bottom surface, and therefore faces away from the substrate, is sometimes herein referred to as a top surface, again only indicating an orientation relative to the substrate of the transistor device. The terms up and down are used in a similar sense herein.

The specification and drawings are, accordingly, to be regarded in an illustrative rather than a restrictive sense. It will, however, be evident that various modifications and changes may be made thereunto without departing from the broader spirit and scope of the disclosure as set forth in the claims.

Other variations are within the spirit of the present disclosure. Thus, while the disclosed techniques are susceptible to various modifications and alternative constructions, certain illustrated embodiments thereof are shown in the drawings and have been described above in detail. It should be understood, however, that there is no intention to limit the disclosure to the specific form or forms disclosed, but on the contrary, the intention is to cover all modifications, alternative constructions and equivalents falling within the spirit and scope of the disclosure, as defined in the appended claims.

The use of the terms “a” and “an” and “the” and similar referents in the context of describing the disclosed embodiments (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted. The term “connected” is to be construed as partly or wholly contained within, attached to, or joined together, even if there is something intervening. The phrase “based on” should be understood to be open-ended, and not limiting in any way, and is intended to be interpreted or otherwise read as “based at least in part on,” where appropriate. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate embodiments of the disclosure and does not pose a limitation on the scope of the disclosure unless otherwise claimed. No language in the specification should be construed as indicating any non-claimed element as essential to the practice of the disclosure.

Disjunctive language such as the phrase “at least one of X, Y, or Z,” unless specifically stated otherwise, is otherwise understood within the context as used in general to present that an item, term, etc., may be either X, Y, or Z, or any combination thereof (e.g., X, Y, and/or Z). Thus, such disjunctive language is not generally intended to, and should not, imply that certain embodiments require at least one of X, at least one of Y, or at least one of Z to each be present. Additionally, conjunctive language such as the phrase “at least one of X, Y, and Z,” unless specifically stated otherwise, should also be understood to mean X, Y, Z, or any combination thereof, including “X, Y, and/or Z.”

Preferred embodiments of this disclosure are described herein, including the best mode known to the inventors for carrying out the disclosure. Variations of those preferred embodiments may become apparent to those of ordinary skill in the art upon reading the foregoing description. The inventors expect skilled artisans to employ such variations as appropriate, and the inventors intend for the disclosure to be practiced otherwise than as specifically described herein. Accordingly, this disclosure includes all modifications and equivalents of the subject matter recited in the claims appended hereto as permitted by applicable law. Moreover, any combination of the above-described elements in all possible variations thereof is encompassed by the disclosure unless otherwise indicated herein or otherwise clearly contradicted by context.

All references, including publications, patent applications, and patents, cited herein are hereby incorporated by reference to the same extent as if each reference were individually and specifically indicated to be incorporated by reference and were set forth in its entirety herein.

What is claimed is:

1. An electronic device comprising:
a package base comprising:
a first external terminal and a second external terminal disposed at a bottom surface of the package base;
an electrically insulative layer having a first thickness defined between a first surface and a second surface;
a plurality of electrically conductive bars extending from the first terminal to the first surface;
a plurality of first electrically conductive terminals disposed on each of the electrically conductive bars at the first surface; and
a plurality of second electrically conductive terminals disposed on the first surface of the electrically insulative layer, each of the second electrically conductive terminals disposed between adjacent first electrically conductive terminals;
a semiconductor device attached to the plurality of first electrically conductive terminals and to the plurality of second electrically conductive terminals; and
an electrically insulative material encapsulating at least a portion of the semiconductor device and the package base.

2. The electronic device of claim 1, wherein the semiconductor device comprises a plurality of source contacts and a plurality of drain contacts arranged in an interdigitated pattern.

3. The electronic device of claim 2, wherein the plurality of source contacts are electrically coupled to the plurality of second electrically conductive terminals and the plurality of drain contacts are electrically coupled to the plurality of first electrically conductive terminals.

4. The electronic device of claim 1, further comprising an electrically conductive via extending through the electrically insulative layer and electrically coupling at least one of the plurality of second electrically conductive terminals to the second external terminal.

5. The electronic device of claim 4, further comprising an electrically conductive collector disposed on the first surface of the electrically insulative layer and electrically coupled to the plurality of second electrically conductive terminals, wherein the electrically conductive collector is electrically coupled to the second external terminal through the electrically conductive via.

6. The electronic device of claim 1, wherein the semiconductor device comprises gallium nitride.

7. The electronic device of claim 2, wherein the plurality of source contacts and the plurality of drain contacts have substantially similar widths.

8. An electronic device comprising:
a semiconductor die including a plurality of source contacts interdigitated with a plurality of drain contacts;
a plurality of electrically conductive drain bars aligned with and attached to the plurality of drain contacts;
an exterior drain terminal attached to the plurality of electrically conductive drain bars;
a plurality of electrically conductive source bars aligned with and attached to the plurality of source contacts;
an exterior source terminal electrically connected to each of the plurality of electrically conductive source bars; and
one or more electrically insulative materials at least partially encapsulating the semiconductor die and the plurality of electrically conductive drain bars.

9. The electronic device of claim 8, wherein a first electrically insulative material at least partially encapsulates the semiconductor die and a second electrically insulative material at least partially encapsulates the drain bars.

10. The electronic device of claim 8, wherein the second electrically insulative material is formed as a layer having a top surface opposite a bottom surface and wherein each of the exterior drain terminal and the exterior source terminal are at the bottom surface.

11. The electronic device of claim 10, further comprising an electrically conductive source via extending through the layer and electrically connecting the exterior source terminal to the plurality of electrically conductive source bars.

12. The electronic device of claim 10, further comprising an electrically conductive source collector electrically coupled to each of the plurality of electrically conductive source bars and wherein the electrically conductive source via electrically connects the source collector to the exterior source terminal.

13. The electronic device of claim 8, wherein the semiconductor die comprises gallium nitride.

14. The electronic device of claim 8, wherein the plurality of source contacts and the plurality of drain contacts have substantially similar widths.

15. A method for forming an electronic device, the method comprising:
providing a package base comprising a first external terminal and a second external terminal disposed at a bottom surface of the package base;
forming an electrically insulative layer having a thickness defined between a first surface and a second surface;
forming a plurality of electrically conductive bars extending from the first terminal to the first surface;
disposing a plurality of first electrically conductive terminals on each of the electrically conductive bars at the first surface;
disposing a plurality of second electrically conductive terminals on the first surface of the electrically insulative layer, each of the second electrically conductive terminals disposed between adjacent first electrically conductive terminals;
attaching a semiconductor device to the plurality of first electrically conductive terminals and to the plurality of second electrically conductive terminals; and
encapsulating at least a portion of the semiconductor device and the package base with an electrically insulative material.

16. The method of claim 15, wherein the semiconductor device comprises a plurality of source contacts and a plurality of drain contacts arranged in an interdigitated pattern.

17. The method of claim 16, wherein attaching the semiconductor device comprises electrically coupling the plurality of source contacts to the plurality of second electrically conductive terminals and electrically coupling the plurality of drain contacts to the plurality of first electrically conductive terminals.

18. The method of claim 15, further comprising forming an electrically conductive via extending through the electrically insulative layer and electrically coupling at least one of the plurality of second electrically conductive terminals to the second external terminal.

19. The method of claim 18, further comprising forming an electrically conductive collector disposed on the first surface of the electrically insulative layer and electrically coupled to the plurality of second electrically conductive terminals, wherein the electrically conductive collector is electrically coupled to the second external terminal through the electrically conductive via.

20. The method of claim 15, wherein the semiconductor device comprises gallium nitride.
